(19) United States
(12) Patent Application Publication
(10) Pub. No.: US 2018/0337668 A1
(43) Pub. Date: Nov. 22, 2018

(54) SEMICONDUCTOR MODULE, SWITCHING ELEMENT SELECTING METHOD USED FOR SEMICONDUCTOR MODULE, AND CHIP DESIGNING METHOD FOR SWITCHING ELEMENT

(71) Applicant: FUJI ELECTRIC CO., LTD., Kawasaki (JP)

(72) Inventor: Nobuhiro HIGASHI, Kawasaki (JP)

(73) Assignee: FUJI ELECTRIC CO., LTD., Kawasaki (JP)

(21) Appl. No.: 16/049,049

(22) Filed: Jul. 30, 2018

Related U.S. Application Data
(63) Continuation of application No. PCT/JP2017/025327, filed on Jul. 12, 2017.

(30) Foreign Application Priority Data
Aug. 18, 2016 (JP) 2016-160318

(51) Int. Cl. H03K 17/082; G06F 17/50

(52) U.S. Cl. CPC H03K 17/0828; G06F 17/5068; H02M 7/537; H03K 2217/0072; H03K 2217/0063

(57) ABSTRACT

The present invention achieves a low loss, chip downsizing, and low cost for a semiconductor module provided with a high-side switching element and a low-side switching element that are complementarily driven on/off. This semiconductor module is provided with a high-side switching element and a low-side switching element that are connected in series so as to be complementarily driven on/off, and used by having an overcurrent detection shunt resistor interposed between the ground potential and the low potential side of the low-side switching element, wherein an element lower in short-circuit resistance than the low-side switching element is used as the high-side switching element. Preferably, an element smaller in chip size and smaller in conduction loss than the low-side switching element is used as the high-side switching element.

### TECHNICAL FIELD

The present invention relates to a semiconductor module which includes a high-side switching element and a low-side switching element that are connected in series and complementarily driven on/off, and which is used by interposing an overcurrent detection shunt-resistor between the low potential side of the low-side switching element and a ground potential, and also relates to a switching element selecting method used for the semiconductor module, and a chip designing method of the switching element used for the semiconductor module.

### BACKGROUND ART

An inverter is known as a power converter for driving a load such as an AC motor. This kind of inverter (power converter) is configured basically by including switching elements such as power MOS-FETs or IGBTs and a drive circuit for driving on/off the switching elements. In order to downsize the inverter, both the switching elements and the drive circuit are packaged together with various kinds of protection circuits as a semiconductor module so-called an IPM (Intelligent Power Module).

FIG. 5 is a schematic configuration diagram showing an example of a power semiconductor device (inverter) 10 of a conventional art, in which a reference numeral 1 denotes a semiconductor module packaged as an intelligent power module (IPM). The semiconductor module (IPM) 1 includes a plurality of (three) half bridge circuits which includes high-side switching elements 2u, 2v, 2w and low-side switching elements 3u, 3v, 3w respectively connected in series thereto, and are provided in parallel between a power supply terminal P and ground terminals N(U), N(V), N(W).

Although this example shows the case in which the IGBTs are used as the switching elements 2u, 2v, 2w, 3u, 3v, 3w, power MOS-FETs may also be used as the switching elements. Freewheeling diodes 4u, 4v, 4w, 5u, 5v, 5w are connected in inverse-parallel to the switching elements (IGBTs) 2u, 2v, 2w, 3u, 3v, 3w, respectively.

The high-side switching elements 2u, 2v, 2w and the low-side switching elements 3u, 3v, 3w, which form the three half bridge circuits arranged in parallel, are complimentarily driven on/off by high-side drive circuits (HVICs) 7u, 7v, 7w and a low-side drive circuit (LVIC) 8 at predetermined phases, specifically, phases (U-phase, V-phase, W-phase) different by 120 degrees to each other, respectively. The semiconductor module 1 outputs three phase (U-phase, V-phase, W-phase) alternating currents for driving a motor M as a load from respective midpoints of the three half bridge circuits.

The midpoints of the three half bridge circuits are a midpoint between the high-side switching element 2u and the low-side switching element 3u, a midpoint between the high-side switching element 2v and the low-side switching element 3v, and a midpoint between the high-side switching element 2w and the low-side switching element 3w.

An overcurrent detection shunt resistor Rs is interposed between the low potential side of the low-side switching elements 3u, 3v, 3w (emitter side of IGBTs) and a ground potential GND. The low-side drive circuit (LVIC) 8 of the semiconductor module 1 includes an overcurrent protection circuit which, when detecting an overcurrent flowing in the switching elements (IGBTs) 2u, 2v, 2w, 3u, 3v, 3w through the shunt resistor Rs, forcibly turns off these switching elements (IGBTs) 2u, 2v, 2w, 3u, 3v, 3w to execute overcurrent protection.

The low-side drive circuit 8 operates using voltages Vs, generated at individual midpoints of the half bridge circuits as a power supply voltage, and using the ground potential GND as a reference potential. The high-side drive circuits 7u, 7v, 7w operate by receiving a predetermined power supply voltage Vcc, using the voltages (midpoint voltages) generated at respective midpoints of the half bridge circuits as a reference potential. The high-side drive circuits 7u, 7v, 7w and the low-side drive circuit 8 complimentarily drive on/off the high-side switching elements 2u, 2v, 2w and the low-side switching elements 3u, 3v, 3w respectively in accordance with control signals Uin, Vin, Win which are supplied from a microprocessor unit (MPU) as a host control device of the drive circuits.

The power converter (inverter) 10 which is achieved using the semiconductor module (IPM) 1 and the shunt resistor Rs configured in this manner is presented in detail, for example, in Patent Document 1, and the like.

### PRIOR ART DOCUMENT

### Patent Document

Patent Document 1: JP-A-2011-61896

### SUMMARY OF THE INVENTION

### Problem to be Solved by the Invention

As described above, the overcurrent detection shunt resistor Rs is connected on the low potential side of the low-side switching elements 3u, 3v, 3w (emitter side of IGBTs) in the semiconductor module 1. Thus, when the low-side switching element 3u (3v, 3w) is turned on, a voltage is generated between both terminals of the shunt resistor Rs due to a drive current Ic of the switching element. Then, a gate voltage Vge of the low-side switching element 3u (3v, 3w) decreases according to the generated voltage, and thus a collector-emitter voltage Vce of the low-side switching element 3u (3v, 3w) increases undeniably.

In particular, for example, when short circuit occurs at the high-side switching element 2u (2v, 2w), an excessive short-circuit current flows at the time of turning-on of the low-side switching element 3u (3v, 3w) as shown in FIG. 6 by an example. However, in general, it takes time to detect the excessive short-circuit current via the shunt resistor Rs and perform the overcurrent protection described above, and thus element breakage of the low-side switching element 3u (3v, 3w) is sometimes caused.

FIG. 6 is an example showing time changes in the voltages and the current of the low-side switching element 3u (3v, 3w) when arm short-circuit occurs. In this figure, a represents an input voltage Vin, b represents the collector-emitter voltage Vce, and c represents a collector current Ic.

In the conventional art, the low-side switching element 3u (3v, 3w) is turned on/off in a state where the high-side switching element 2u (2v, 2w) is set to an on state, and the collector-emitter voltage Vce and the drive current Ic in short circuit at the time of turning-on of the low-side switching element 3u (3v, 3w) are measured using a test circuit configured, for example, as shown in FIG. 7. An energy generated in short circuit is obtained from the measured collector-emitter voltage Vce, the measured drive current Ic in short circuit, and a short-circuit period. A short-circuit tolerance necessary for the low-side switching element 3u (3v, 3w) is obtained based on the obtained energy in short circuit, and an IGBT (or power MOS-FET) with element characteristics satisfying the short-circuit tolerance are selected as the low-side switching element 3u (3v, 3w).

When a short circuit failure (arm short-circuit) occurs in any one of the switching elements 2u, 2v, 2w, 3u, 3v, 3w, the gate voltage of the low-side switching element 3u (3v, 3w) decreases as described above. Thus, an energy in short circuit concentrates on the low-side switching element 3u (3v, 3w). Consequently, the low-side switching element 3u (3v, 3w) is required to have a higher short-circuit tolerance than the high-side switching element 2u (2v, 2w).

In the conventional art, however, solely the semiconductor module 1 is configured by merely selecting, as the high-side switching elements 2u, 2v, 2w, IGBTs (or power MOS-FETs) having the same element characteristics as those of the low-side switching elements 3u, 3v, 3w. In other words, it should be stated that the short-circuit tolerance of the high-side switching element 2u, 2v, 2w is excessive.

As a result, an on voltage of the high-side switching element 2u, 2v, 2w capable of satisfying the excessive short-circuit tolerance increases, and thus there arises a problem that a conduction loss of this switching element increases accompanied by the increased on voltage. Further, the short-circuit tolerance of the high-side switching element 2u, 2v, 2w also relates to a collector-emitter saturation voltage Vce(sat) of the high-side switching element 2u, 2v, 2w. Thus, there arises such a problem that it is necessary to suppress the collector-emitter saturation voltage Vce(sat) by selecting elements with a large chip size as the high-side switching elements 2u, 2v, 2w.

The invention has been made in view of the above circumstances, and an object thereof is to achieve a low loss, chip downsizing, and low cost for a semiconductor module which is provided with a high-side switching element and a low-side switching element that are complimentarily driven on/off and which is used by connecting a shunt resistor to the low potential side of the low-side switching element.

### Means for Solving the Problem

In order to attain the object described above, a semiconductor module according to the present invention includes:

a high-side switching element and a low-side switching element which are connected in series and provided between a power supply terminal and a ground terminal;

freewheeling diodes which are connected in inverse-parallel to the respective switching elements; and

a high-side drive circuit and a low-side drive circuit which complimentarily drive on/off the high-side switching element and the low-side switching element,

wherein the semiconductor module is used by interposing an overcurrent detection shunt resistor between the low potential side of the low-side switching element and a ground potential.

In particular, in the semiconductor module according to the present invention, an element having a lower short-circuit tolerance than the low-side switching element is used as the high-side switching element.

The short-circuit tolerance of the low-side switching element is set based on an energy applied to the low-side switching element when the low-side switching element is turned on in an on state of the high-side switching element. The short-circuit tolerance of the high-side switching element is set based on an energy applied to the high-side switching element when the high-side switching element is turned on in an on state of the low-side switching element.

Preferably, an element having a smaller conduction loss than the low-side switching element is used as the high-side switching element. An element having a smaller chip size than the low-side switching element is used as the high-side switching element. The high-side switching element and the low-side switching element are each formed of, for example, an IGBT or a power MOS-FET.

The high-side drive circuit is configured to operate by receiving a predetermined power supply voltage, using a voltage at a midpoint of the high-side switching element and the low-side switching element connected in series as a reference potential, thereby driving on/off the high-side switching element. The low-side drive circuit is configured to drive on/off the low-side switching element using a voltage generated at the midpoint as a power supply voltage and using a potential of the ground terminal as a reference potential.

Preferably, a plurality of half bridge circuits each includes the high-side switching element and the low-side switching element connected in series are provided in parallel to each other so as to be interposed between the power supply terminal and the ground terminal. The high-side switching elements and the low-side switching elements constituting the plurality of half bridge circuits provided in parallel are complimentarily driven on/off with a predetermined phase difference.

A conduction loss reducing method according to the present invention is a method of reducing a conduction loss generated in a semiconductor module which includes a high-side switching element and a low-side switching element connected in series and provided between a power supply terminal and a ground terminal, and a high-side drive circuit and a low-side drive circuit for complementarily driving on/off the high-side switching element and the low-side switching element, and for which an overcurrent detection shunt resistor is interposed between the ground terminal and a ground potential, the conduction loss reducing method includes:

obtaining an energy applied to the low-side switching element based on a collector-emitter voltage of the low-side switching element when the low-side switching element is turned on in an on state of the high-side switching element, a collector current in short circuit, and a short-circuit period;

obtaining an energy applied to the high-side switching element based on a collector-emitter voltage of the high-side switching element when the high-side switching element is turned on in an on state of the low-side switching element, a collector current in short circuit, and a short-circuit period; and

applying, to the high-side switching element, an element which is designed to have a lower short-circuit tolerance than the low-side switching element based on the energy applied to the low-side switching element and the energy applied to the high-side switching element, thereby lowering a conduction loss having a proportional relation to the short-circuit tolerance.

A switching element selecting method for a semiconductor module according to the present invention is a method of selecting a switching element for the semiconductor module which includes a high-side switching element and a low-side switching element connected in series and provided between a power supply terminal and a ground terminal, and a drive circuit for driving the high-side switching element and the low-side switching element, and for which an overcurrent detection shunt resistor is interposed between the ground terminal and a ground potential, the switching element selecting method includes:

obtaining an energy applied to the low-side switching element based on a collector-emitter voltage of the low-side switching element when the low-side switching element is turned on in an on state of the high-side switching element, a collector current in short circuit, and a short-circuit period;

obtaining an energy applied to the high-side switching element based on a collector-emitter voltage of the high-side switching element when the high-side switching element is turned on in an on state of the low-side switching element, a collector current in short circuit, and a short-circuit period; and

selecting the high-side switching element based on the obtained energy applied to the low-side switching element and the obtained energy applied to the high-side switching element, with reference to the low-side switching element.

A chip designing method of a switching element according to the present invention is a method of designing a high-side switching element for a semiconductor module which includes the high-side switching element and a low-side switching element connected in series and provided between a power supply terminal and a ground terminal, and a high-side drive circuit and a low-side drive circuit for complementarily driving on/off the high-side switching element and the low-side switching element, and in which an overcurrent detection shunt resistor is interposed between the ground terminal and a ground potential, the chip designing method includes:

obtaining an energy applied to the low-side switching element based on a collector-emitter voltage when the low-side switching element is turned on in an on state of the high-side switching element, a collector current in short circuit, and a short-circuit period;

obtaining an energy applied to the high-side switching element based on a collector-emitter voltage when the high-side switching element is turned on in an on state of the low-side switching element, a collector current in short circuit, and a short-circuit period;

determining a collector-emitter saturation voltage of the high-side switching element based on the obtained energy applied to the low-side switching element and the obtained energy applied to the high-side switching element, with reference to a collector-emitter saturation voltage of the low-side switching element; and

determining a size of the high-side switching element based on the collector-emitter saturation voltage of the high-side switching element.

The present invention intends, in particular, to lower a short-circuit tolerance of the high-side switching element by noticing the energies, thereby lowing a condition loss in the entirety of the semiconductor module. The chip of the high-side switching element can be downsized in proportional to the short-circuit tolerance lowered than that of the low-side switching element.

### Effects of Invention

According to the semiconductor module configured in the aforesaid manner, as compared with a short-circuit tolerance of the low-side switching element which is set in consideration of a voltage generated in the shunt resistor, an element having a lower short-circuit tolerance than the low-side switching element is used as the high-side switching element. Thus, a conduction loss of the high-side switching element can be suppressed small. Further, the chip size of the high-side switching element can be reduced as compared with that of the low-side switching element. Accordingly, effects can be attained such that a low loss and low cost of the semiconductor module can be achieved, and chip downsizing in the entirety of the semiconductor module can be achieved.

In order to determine a short-circuit tolerance of the high-side switching element, for example, the high-side switching element is turned on/off in an on state of the low-side switching element. Then, a collector-emitter voltage Vce and a drive current Ic in short circuit at the time of turning-on of the high-side switching element are measured. An energy generated in short circuit is obtained from the measured collector-emitter voltage Vce, the measured drive current Ic in short circuit, and a short-circuit period. The short-circuit tolerance of the high-side switching element may be determined based on the obtained energy generated in short circuit.

The energy generated in short circuit of the high-side switching element is not affected by a voltage generated across the shunt resistor. Thus, when the short-circuit tolerance necessary for the high-side switching element is obtained based on the energy generated in short circuit in the manner described above, the short-circuit tolerance of the high-side switching element can be lowered than that of the low-side switching element.

Consequently, according to the present invention, the short-circuit tolerance required for the high-side switching element can be set suitably without being affected by the short-circuit tolerance required for the low-side switching element. Accordingly, a low loss and low cost of the semiconductor module, and downsizing of the chip can be achieved.

### BRIEF DESCRIPTION OF THE DRAWINGS

FIG. 1 is a diagram showing an example of a measuring circuit which measures a collector-emitter voltage Vce and a drive current Ic in short circuit of a high-side switching element in order to suitably set a short-circuit tolerance of the high-side switching element in a semiconductor module according to the present invention.

FIG. 2 is a diagram showing a conduction loss of the high-side switching element according to the present invention, which has a lower short-circuit tolerance than a low-side switching element, in comparison with a conduction loss of a high-side switching element having the same short-circuit tolerance as a low-side switching element.

FIG. 3 is a diagram showing a simulation result in which a loss of the semiconductor module according to the present invention and a loss of a semiconductor module of a conventional art are shown in a comparative manner.

FIG. 4 is a diagram showing downsizing of a chip of the semiconductor module according to the present invention in comparison with a chip size of the semiconductor module of the conventional art.

FIG. 5 is a schematic configuration diagram showing an example of the semiconductor module of the conventional art.

FIG. 6 is a diagram showing a change state of a current Ic flowing in the low-side switching element and a collector-emitter voltage Vce when arm short-circuit occurs.

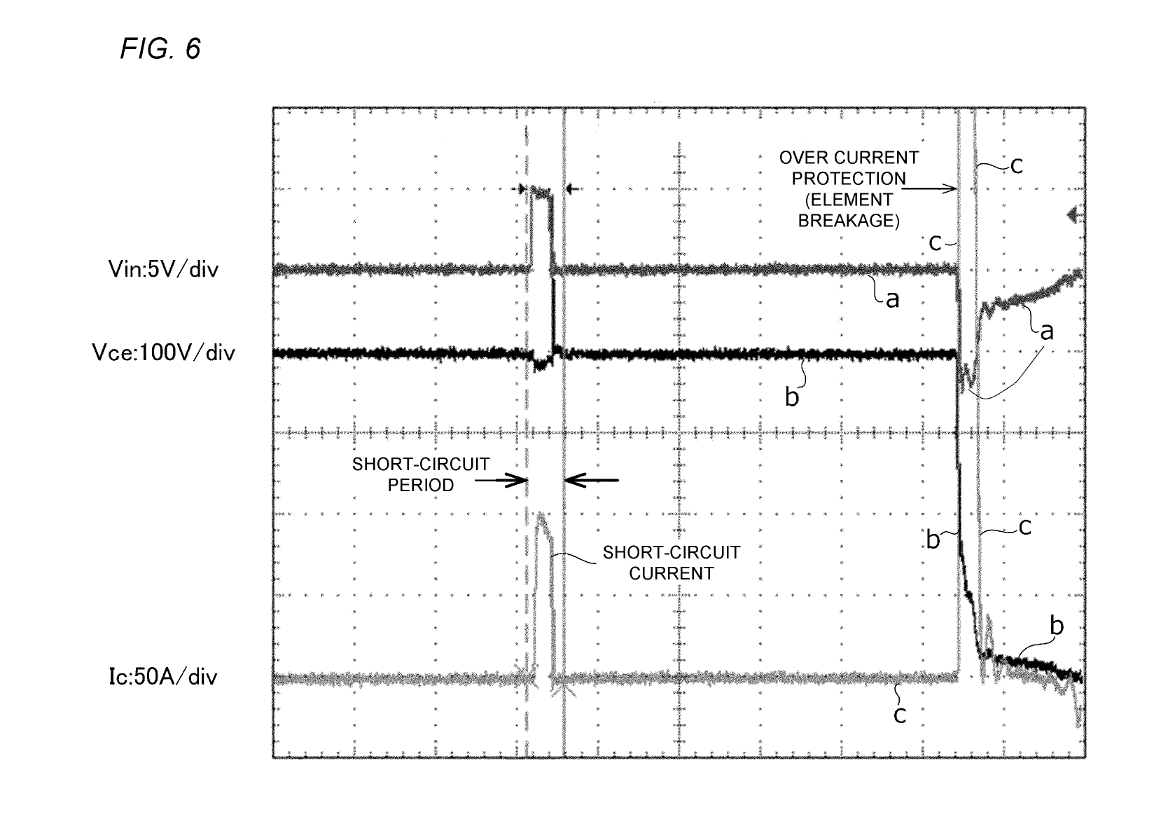

FIG. 7 is a diagram showing a configuration example of a test circuit of a semiconductor module.

### DETAILED DESCRIPTION OF EMBODIMENTS

Hereinafter a semiconductor module (IPM) 1 according to an embodiment of the present invention will be explained with reference to drawings.

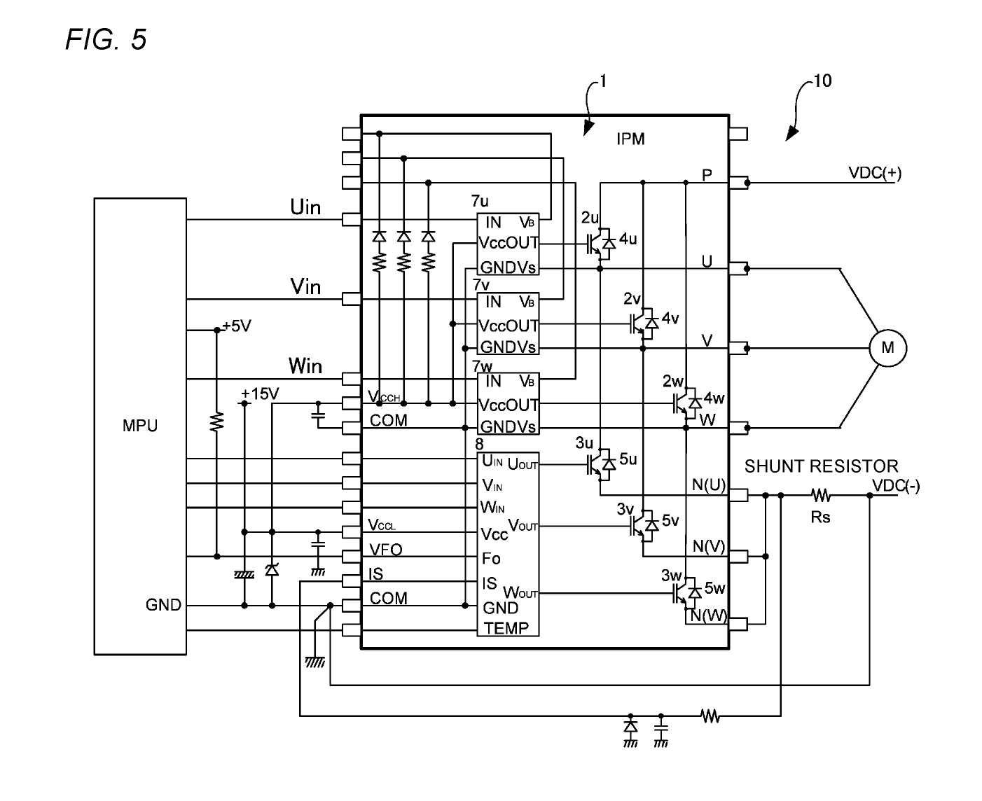

The semiconductor module 1 according to the present invention is configured basically in the similar way, in the circuit configuration, as the semiconductor module 1 of the conventional art shown in FIG. 5. Thus, explanation of the configuration of the semiconductor module 1 will be omitted. The semiconductor module 1 according to the present invention is characterized by using, as high-side switching elements, elements each having a short-circuit tolerance lower than that of low-side switching elements, and so differs from the semiconductor module 1 of the conventional art in this point.

That is, the semiconductor module 1 of the conventional art uses, as the high-side switching elements 2u, 2v, 2w, the elements each having the short-circuit tolerance identical with that of the low-side switching elements 3u,3v, 3w. In contrast, the semiconductor module 1 according to the invention is characterized by using, as new high-side switching elements 6u, 6v, 6w in place of the high-side switching elements 2u, 2v, 2w, for example, elements (IGBTs) each having a short-circuit tolerance lower than that of the low-side switching elements 3u,3v, 3w formed of IGBTs

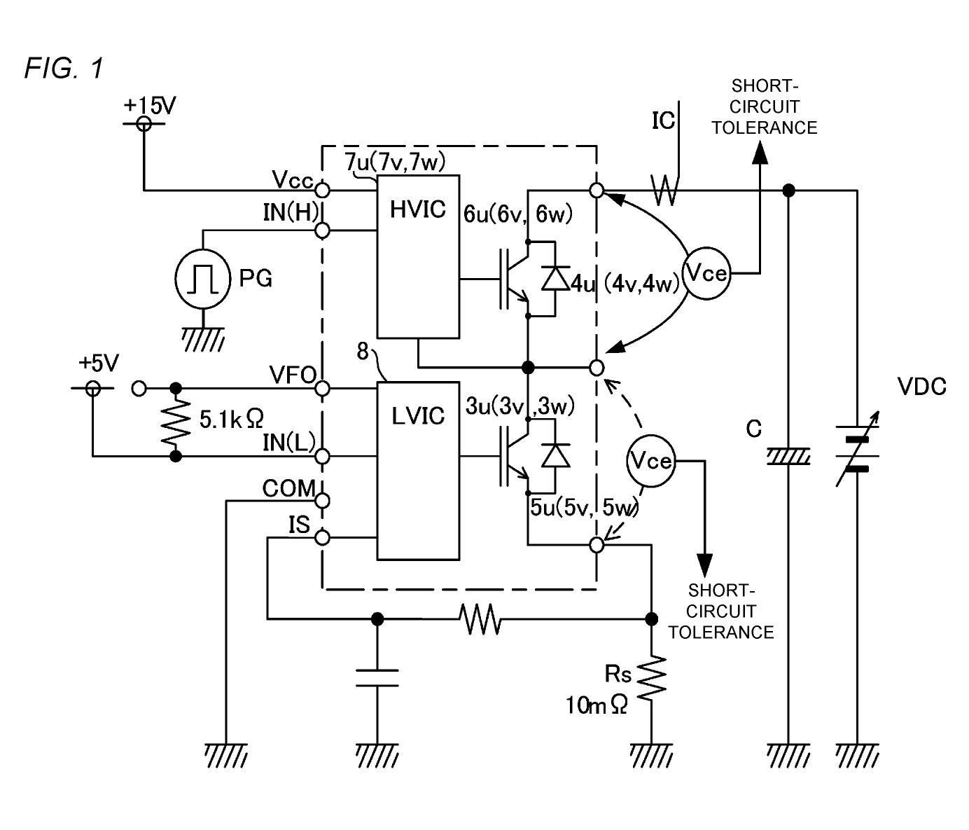

Concerning the short-circuit tolerance of the newly employed high-side switching elements 6u, 6v, 6w, the high-side switching element 6u (6v, 6w) is turned on/off in a state where the low-side switching element 3u (3v, 3w) is set to an on state, and a collector-emitter voltage Vce and a drive current Ic in short circuit at the time of turning-on of the high-side switching element 6u (6v, 6w) are measured using a measuring circuit, for example, shown in FIG. 1. The short-circuit tolerance necessary for the high-side switching element 6u (6v, 6w) is obtained based on an energy generated in short circuit which is obtained from the measured collector-emitter voltage Vce, the measured drive current Ic in short circuit, and a short-circuit period. Then, an IGBT (or power MOS-FET) with element characteristics satisfying the short-circuit tolerance obtained in the aforesaid manner is determined as the new high-side switching element 6u (6v, 6w).

Supporting that the collector-emitter voltage is VCE(t), the drive current in short circuit is IC(t), and the short circuit period is a period from t1 to t2, the energy E can be represented by the following formula.

E=∫ₜ₁^{t2}[VCE(t)×IC(t)]dt

Practically, VCE(t) and IC(t) at the time of the breakage of the element are measured and recorded using a measuring device, values of VCE(t) and IC(t) are read at a constant time interval and numerically integrated using a spreadsheet or the like, and thus the energy E can be obtained.

When a short circuit failure (arm short-circuit) occurs in any one of the switching elements 6u, 6v, 6w, 3u, 3v, 3w, the gate voltage of the low-side switching element 3u (3v, 3w) decreases due to a voltage generated across a shunt resistor Rs, as described above. Thus, the energy in short circuit concentrates on the low-side switching element 3u (3v, 3w). However, the gate voltage of the high-side switching element 6u (6v, 6w) does not decrease by the voltage generated across the shunt resistor Rs, and the energy in short circuit does not concentrate on the high-side switching element 6u (6v, 6w).

In other words, a current flowing in the high-side switching element 6u (6v, 6w) is not affected by the shunt resistor Rs. Thus, even when the short-circuit tolerance necessary for the high-side switching element 6u (6v, 6w) is calculated based on the energy generated in short circuit which is obtained from the collector-emitter voltage Vce and the drive current Ic in short circuit, at the time of turning-on of the high-side switching element 6u (6v, 6w) each measured in the aforesaid manner, and the short-circuit period, no failure is caused in the operation characteristics of the semiconductor module 1.

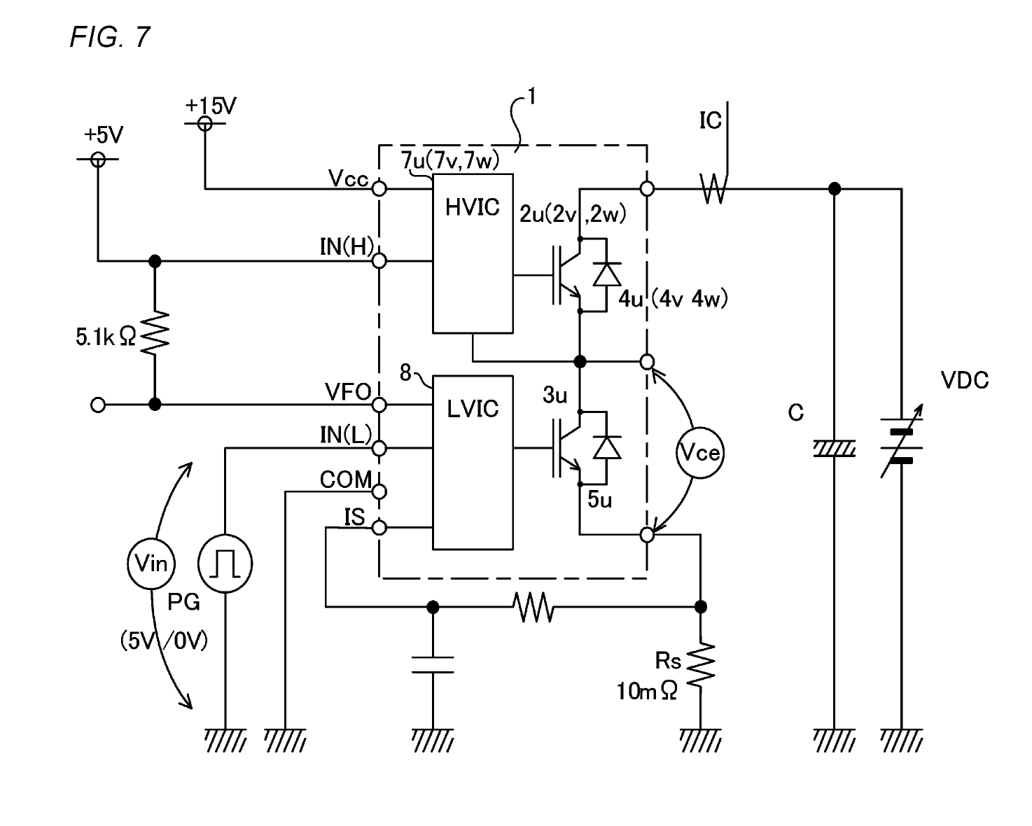

Further, as compared with the collector-emitter voltage Vce at the time of turning-on of the low-side switching element 3u (3v, 3w) measured by the test circuit shown in FIG. 7, the collector-emitter voltage Vce at the time of turning-on of the high-side switching element 6u (6v, 6w) which is measured by the measuring circuit shown in FIG. 1 is not affected by the shunt resistor Rs, and thus becomes lower correspondingly. Thus, the short-circuit tolerance necessary for the high-side switching element 6u (6v, 6w), which is determined based on the energy generated in short circuit which is obtained from the collector-emitter voltage Vce, the drive current Ic in short circuit, and the short-circuit period, becomes lower than the aforesaid short-circuit tolerance necessary for the low-side switching element 3u (3v, 3w).

Accordingly, the semiconductor module 1 according to the present invention, in which the element having the lower short-circuit tolerance lower than the low-side switching element 3u (3v, 3w) is employed as the high-side switching element 6u (6v, 6w), can also stably operate without being affected by the shunt resistor Rs. The short-circuit tolerance of the high-side switching element 6u (6v, 6w) is made lower, and thus a conduction loss of the high-side switching element 6u (6v, 6w) can be suppressed to be small correspondingly. Further, a chip size of the high-side switching element can also be suppressed to be small correspondingly. In this manner, the high-side switching element has a lot of practical advantages.

In general, the short-circuit tolerance has a proportional relation with the collector-emitter saturation voltage Vce(sat), and the collector-emitter saturation voltage Vce(sat) also has a proportional relation with the chip size. Thus, when the short-circuit tolerance is made high (low), the chip size becomes large (small). Regarding the short-circuit tolerance as an energy generated in short circuit of the switching element, the collector-emitter saturation voltage Vce(sat) of the high-side switching element 6u (6v, 6w) may be determined, for example, based on a ratio between an energy applied to the low-side switching element 3u (3v, 3w) and an energy applied to the high-side switching element 6u (6v, 6w), using the collector-emitter saturation voltage Vce(sat) of the low-side switching element 3u (3v, 3w) as a reference. Further, the chip size of the high-side switching element 6u (6v, 6w) may be determined based on the collector-emitter saturation voltage Vce(sat) of the high-side switching element.

As another method, the chip size of the high-side switching element 6u (6v, 6w) may be determined based on a ratio between the energy applied to the low-side switching element 3u (3v, 3w) and the energy applied to the high-side switching element 6u (6v, 6w), using the chip size of the low-side switching element 3u (3v, 3w) as a reference.

When simulation is performed for the high-side switching element 6u (6v, 6w) and the low-side switching element 3u (3v, 3w) that are formed of the IGBTs of which the short-circuit tolerances are determined in the aforesaid manner, the following result is obtained. That is, the short-circuit tolerance of the IGBT has a proportional relation with the collector-emitter saturation voltage Vce(sat) thereof, and the collector-emitter saturation voltage Vce(sat) is determined by the chip size thereof. Thus, the chip size of the low-side switching element 3u (3v, 3w) having the high short-circuit tolerance has to be made larger by about 10 to 20% than the chip size of the high-side switching element 6u (6v, 6w) having the low short-circuit tolerance. A cost of the chip for forming the IGBT increases as the required size of the chip thereof becomes larger.

In the IGBTs having the same chip size, the short-circuit tolerance has a proportional relation with an on voltage. Thus, an on voltage of the high-side switching element 2u (2v, 2w) having the same chip size as the low-side switching element 3u (3v, 3w) is higher than an on voltage of the low-side switching element 3u (3v, 3w). Accordingly, a conduction loss of the high-side switching element 2u (2v, 2w) increases by about 10 to 15% compared with a conduction loss of the low-side switching element 3u (3v, 3w).

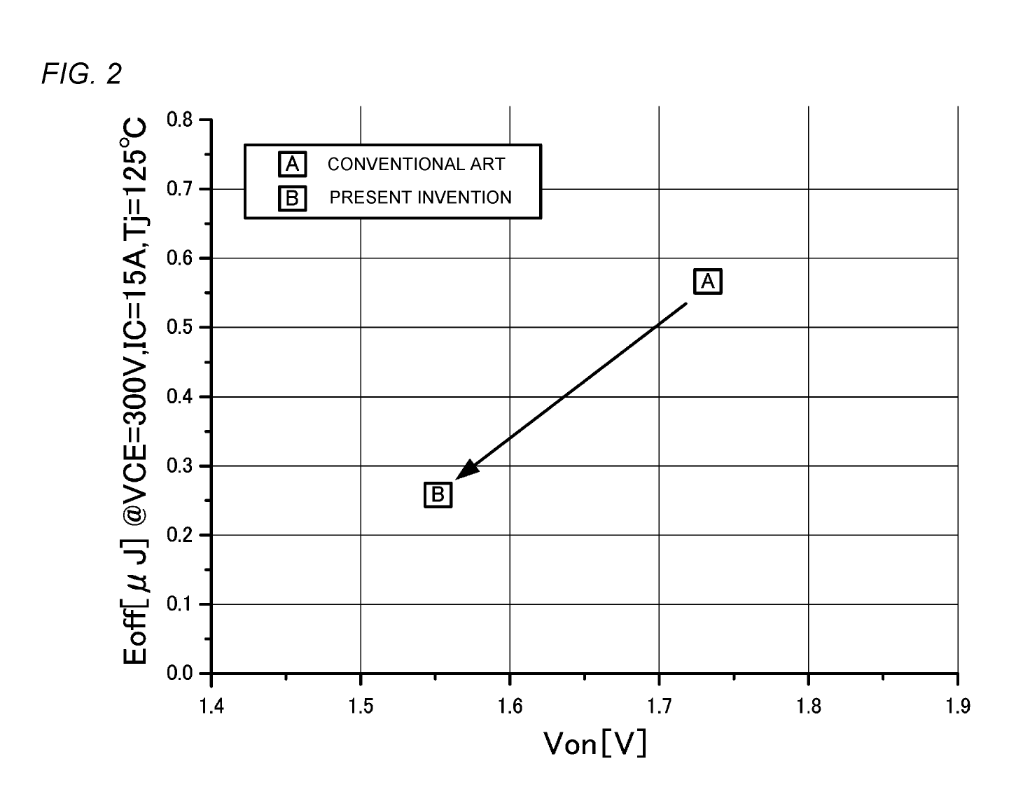

In this respect, according to the high-side switching element 6u (6v, 6w) having the low short-circuit tolerance newly employed in the semiconductor module 1 of the invention, the chip can be downsized as described above, and so the on voltage can be suppressed, for example, to a small value of about 1.55V correspondingly as shown in FIG. 2. Thus, the conduction loss of the high-side switching element 6u (6v, 6w) can be suppressed, for example, to a small value of about 0.25p per 1 module. In other words, the conduction loss of the high-side switching element 6u (6v, 6w) can be suppressed to be small compared with that of the semiconductor module 1 of the conventional art.

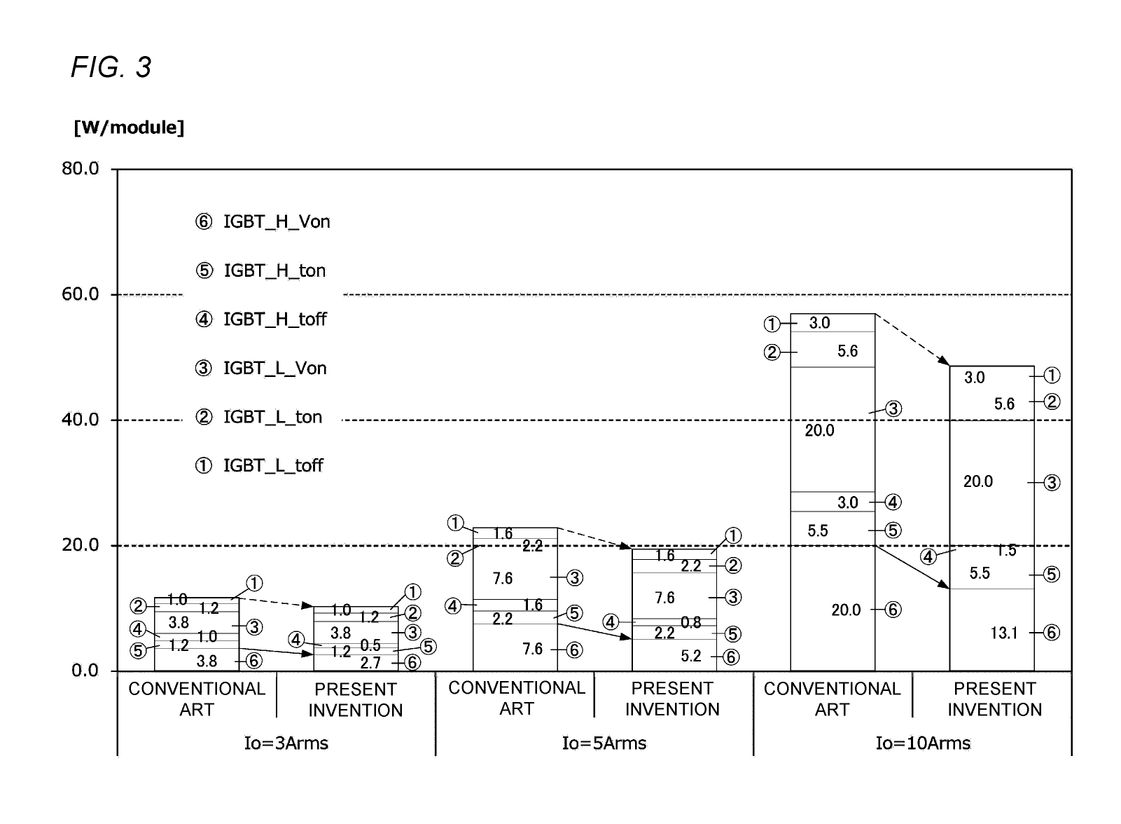

FIG. 3 shows a simulation result in which a loss of the semiconductor module 1 according to the present invention and a loss of the semiconductor module 1 of the conventional art are illustrated in a comparative manner. FIG. 3 shows individual losses and a total loss thereof in the cases where the high-side switching element 2u (2v, 2w), 6u (6v, 6w) and the low-side switching element 3u (3v, 3w) are in an on state (Von), turned on (ton), and turned off (toff).

As is seen from the simulation result shown in FIG. 3, the semiconductor module 1 according to the invention can reduce the loss by about 11.8 to 13.8% compared with the semiconductor module 1 of the conventional art, in a range from an intermediate load (Io=5 A) to a rated load (Io=10 A).

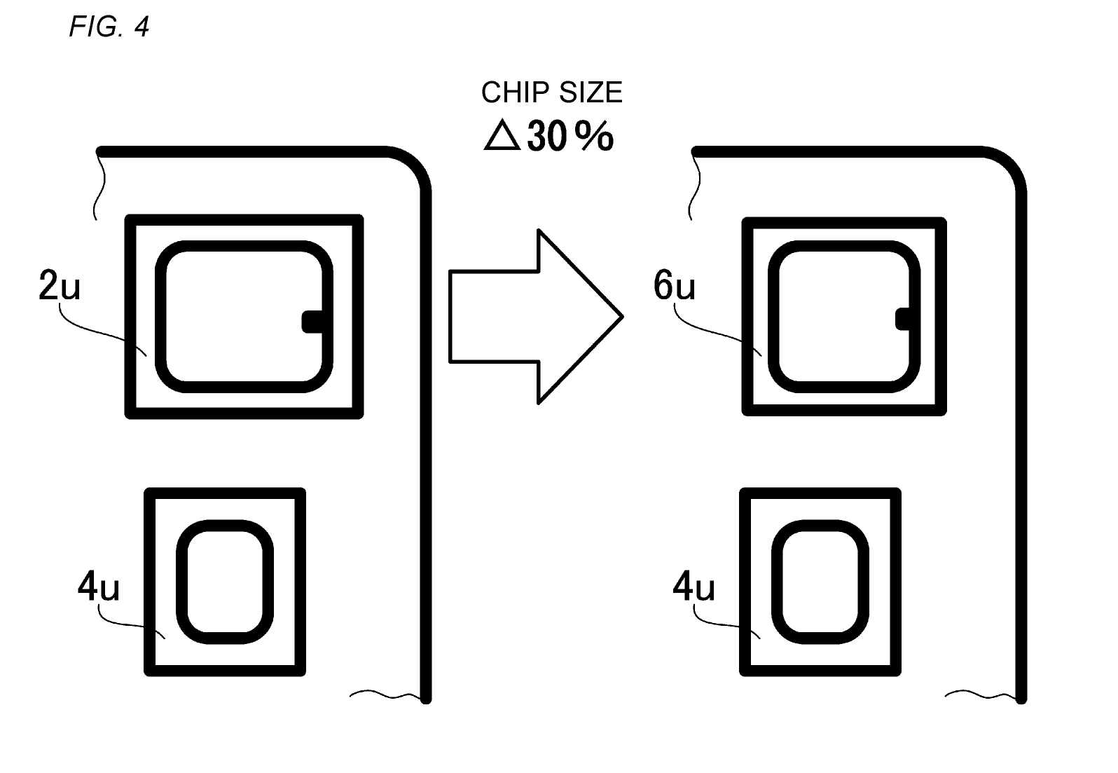

Further, as shown by an example in FIG. 4, the chip size of the high-side switching element 2u (2v, 2w), 6u (6v, 6w) formed of the IGBT can be suppressed to a small value, for example, about 6 to 5 mm² Thus, according to the downsizing of the chip, the cost of the chip can be reduced by about 30%.

The present invention is not limited to the embodiment described above. Heretofore, the explanation is made as to the example of the semiconductor module (IPM) 1 constituting the power converter (inverter) 10 which outputs three-phase (U-phase, V-phase, W-phase) alternating currents. The present disclosure, however, can also be applied in the similar manner to a switching power supply device which includes a set of a high-side switching element and a low-side switching element. As described above, the power MOS-FET may be used as the high-side switching element and the low-side switching element. Moreover, as for the high-side drive circuit for driving on/off the high-side switching elements and the low-side drive circuit for driving on/off the low-side switching elements, various circuits having been proposed can be suitably employed. The present invention can be implemented in such a way as to be changed in various manners in a range not departing from the gist of the present invention.

### REFERENCE SIGNS LIST

1: semiconductor module (IPM)
2u, 2v, 2w: high-side switching element
3u, 3v, 3w: low-side switching element
4u, 4v, 4w, 5u, 5v, 5w: freewheeling diode
6u, 6v, 6w: high-side switching element
7u, 7v, 7w: high-side drive circuit (HVIC)
8: low-side drive circuit (LVIC)
10: power converter (inverter)
Rs: shunt resistor
M: motor (load)

1. A semiconductor module, comprising:
a high-side switching element and a low-side switching element which are connected in series and provided between a power supply terminal and a ground terminal;
freewheeling diodes which are connected in inverse-parallel to the respective switching elements; and
a high-side drive circuit and a low-side drive circuit which complimentarily drive on/off the high-side switching element and the low-side switching element,
wherein the semiconductor module is used by interposing an overcurrent detection shunt resistor between the ground terminal and a ground potential, and
wherein an element having a lower short-circuit tolerance than the low-side switching element is used as the high-side switching element.

2. The semiconductor module according to claim 1,
wherein the short-circuit tolerance of the low-side switching element is set based on an energy applied to the low-side switching element when the low-side switching element is turned on in an on state of the high-side switching element, and
wherein the short-circuit tolerance of the high-side switching element is set based on an energy applied to the high-side switching element when the high-side switching element is turned on in an on state of the low-side switching element.

3. The semiconductor module according to claim 1,
wherein a conduction loss of the high-side switching element is smaller than a conduction loss of the low-side switching element.

4. The semiconductor module according to claim 1,
wherein a chip size of the high-side switching element is smaller than a chip size of the low-side switching element.

5. The semiconductor module according to claim 1,
wherein the high-side switching element and the low-side switching element are each formed of an IGBT or a power MOS-FET.

6. The semiconductor module according to claim 1,
wherein the high-side drive circuit operates by receiving a predetermined power supply voltage, using a voltage at a midpoint of the high-side switching element and the low-side switching element connected in series as a reference potential, thereby driving on/off the high-side switching element, and
wherein the low-side drive circuit drives on/off the low-side switching element by receiving a voltage generated at the midpoint, using a potential of the ground terminal as a reference potential.

7. The semiconductor module according to claim 1,
wherein a plurality of half bridge circuits each including the high-side switching element and the low-side switching element connected in series are provided in parallel to each other between the power supply terminal and the ground terminal, and
wherein the high-side switching elements and the low-side switching elements constituting the plurality of half bridge circuits are complimentarily driven on/off with a predetermined phase difference by a plurality of the high-side drive circuits and a plurality of the low-side drive circuits.

8. A switching element selecting method for a semiconductor module which includes a high-side switching element and a low-side switching element connected in series and provided between a power supply terminal and a ground terminal, and a drive circuit for driving the high-side switching element and the low-side switching element, and for which an overcurrent detection shunt resistor is interposed between the ground terminal and a ground potential, the switching element selecting method comprising:
obtaining an energy applied to the low-side switching element based on a collector-emitter voltage of the low-side switching element when the low-side switching element is turned on in an on state of the high-side switching element, a collector current in short circuit, and a short-circuit period;
obtaining an energy applied to the high-side switching element based on a collector-emitter voltage of the high-side switching element when the high-side switching element is turned on in an on state of the low-side switching element, a collector current in short circuit, and a short-circuit period; and
selecting the high-side switching element based on the obtained energy applied to the low-side switching element and the obtained energy applied to the high-side switching element, with reference to the low-side switching element.

9. A chip designing method of a high-side switching element for a semiconductor module which includes the high-side switching element and a low-side switching element connected in series and provided between a power supply terminal and a ground terminal, and a high-side drive circuit and a low-side drive circuit for complementarily driving on/off the high-side switching element and the low-side switching element, and for which an overcurrent detection shunt resistor is interposed between the ground terminal and a ground potential, the chip designing method comprising:
obtaining an energy applied to the low-side switching element based on a collector-emitter voltage of the low-switching element when the low-side switching element is turned on in an on state of the high-side switching element, a collector current in short circuit, and a short-circuit period;
obtaining an energy applied to the high-side switching element based on a collector-emitter voltage of the high-side switching element when the high-side switching element is turned on in an on state of the low-side switching element, a collector current in short circuit, and a short-circuit period;
determining a collector-emitter saturation voltage of the high-side switching element based on the obtained energy applied to the low-side switching element and the obtained energy applied to the high-side switching element, with reference to a collector-emitter saturation voltage of the low-side switching element; and
determining a size of the high-side switching element based on the collector-emitter saturation voltage of the high-side switching element.
